(19) United States
(12) Patent Application Publication
(10) Pub. No.: US 2017/0288709 A1
(43) Pub. Date: Oct. 5, 2017

(54) AMPLIFICATION APPARATUS

(71) Applicant: FUJITSU LIMITED, Kawasaki-shi (JP)

(72) Inventor: Yuichi Utsunomiya, Kawasaki (JP)

(73) Assignee: FUJITSU LIMITED, Kawasaki-shi (JP)

(21) Appl. No.: 15/468,978

(22) Filed: Mar. 24, 2017

(30) Foreign Application Priority Data
Apr. 1, 2016 (JP) 2016-074598

(51) Int. Cl. H04B 1/04; H03F 1/32; H03F 1/02; H04W 52/52

(52) U.S. Cl. CPC H04B 1/0475; H04W 52/52; H03F 1/32; H03F 1/0288; H04B 2001/0416; H04B 2001/045

(57) ABSTRACT

An amplification apparatus includes a separator configured to separate an input signal into a first signal and a second signal, a first and second amplifiers amplify the first and second signal, a storage, and a processor coupled to the storage and configured to adjust a phase of the second signal on the basis of a first phase value corresponding to a power value of the input signal or a second phase value set within a period in which the first phase value is updated, calculate a power value of an output signal that is synthesis of an output of the first amplifier and an output of the second amplifier, and update the first phase value to the second phase value after the change of the power value of the calculated output signal when the first phase value is the power value of the input signal.

### CROSS-REFERENCE TO RELATED APPLICATION

This application is based upon and claims the benefit of priority of the prior Japanese Patent Application No. 2016-074598, filed on Apr. 1, 2016, the entire contents of which are incorporated herein by reference.

### FIELD

The present embodiments relate to an amplification apparatus.

### BACKGROUND

In various electronic apparatus such as a base station of a mobile communication system, an amplification apparatus that amplifies transmission power is used. In recent years, along with the increase in speed of communication, it is expected to amplify transmission power with a higher efficiency from a point of view of suppression of the consumed power and so forth. The efficiency of an amplification apparatus is highest in an output saturation state (non-linear state), and as an amplification apparatus corresponding to this, an amplification apparatus of the Doherty type (hereinafter referred to as “Doherty amplification apparatus”) has been proposed.

A Doherty amplification apparatus includes a carrier amplifier (CA) and a peak amplifier (PA) coupled in parallel, and the CA and the PA operate in order together with increase of the input power. In the Doherty amplification apparatus, when the input power of the PA increases within a period within which the PA does not operate, the efficiency of the Doherty amplification apparatus may decrease. In this connection, there is a conventional technology which controls distribution of the input power to the CA and the PA by adjusting the phase of a signal inputted to the PA based on the power value of an input signal to or an output signal of the Doherty amplification apparatus.

### CITATION LIST

### Patent Document

[Patent Document 1] Japanese National Publication of International Patent Application No. 2015-514360

### SUMMARY

According to an aspect of the embodiments, an amplification apparatus includes a separator configured to separate an input signal into a first signal and a second signal, a first amplifier configured to amplify the first signal, a second amplifier configured to amplify the second signal, a storage, and a processor coupled to the storage and configured to adjust a phase of the second signal on the basis of a first phase value corresponding to a power value of the input signal or a second phase value set within a period in which the first phase value is updated, calculate a power value of an output signal that is synthesis of an output of the first amplifier and an output of the second amplifier, and update the first phase value to the second phase value after the change of the power value of the calculated output signal when the first phase value is the power value of the input signal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a view illustrating a problem of a conventional technology;

FIG. 2 is a block diagram depicting a configuration of an amplification apparatus according to a working example 1;

FIG. 3 is a view depicting an example of an adjustment table stored in a storage in the working example 1;

FIG. 4 is a flow chart illustrating a phase value updating process according to the working example 1;

FIG. 5 is a flow chart illustrating a phase adjustment process according to the working example 1;

FIG. 6 is a view illustrating an example of operation of an updater in a working example 2;

FIG. 7 is a block diagram depicting a configuration of an amplification apparatus according to a working example 3;

FIG. 8 is a view illustrating an example of operation of an updater in a working example 4;

FIG. 9 is a view depicting an example of an adjustment table stored in a storage in the working example 4;

FIG. 10 is a view illustrating an example of operation of an updater in a working example 5; and

FIG. 11 is a block diagram depicting a configuration of an amplification apparatus according to a working example 6.

### DESCRIPTION OF EMBODIMENTS

The conventional technology described above has a problem in that it is difficult to obtain a sufficiently high efficiency and output power.

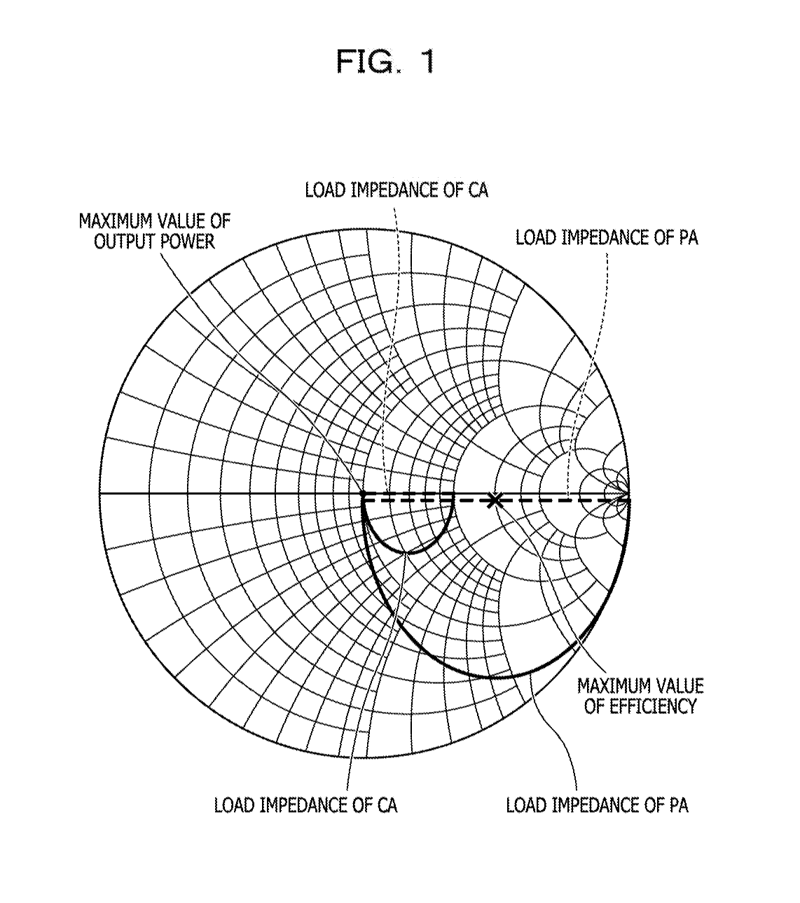

FIG. 1 is a view illustrating a problem of a conventional technology. FIG. 1 is a Smith chart illustrating a locus of the load impedance of a CA and a PA in a Doherty amplification apparatus. It is known that the efficiency and the output power of a Doherty amplification apparatus demonstrate a maximum value where the load impedance of the CA and the PA exists on a real axis of a Smith chart (for example, on a broken line in FIG. 1). However, in the conventional technology, depending upon a result of distribution of input power to the CA and the PA, the load impedance of the CA and the PA is sometimes displaced from the real axis of a Smith chart as indicated by a solid line in FIG. 1. If the load impedance of the CA and the PA is displaced from the real axis of a Smith chart, there is the possibility that both of the efficiency and the output power of the Doherty amplification apparatus may decrease.

The technology disclosed herein has been devised taking the foregoing into consideration and it is an object of the technology disclosed herein to provide an amplification apparatus that may improve the efficiency and the output power.

In the following, working examples of the amplification apparatus disclosed herein are described in detail with reference to the drawings. It is to be noted that the disclosed technology is not limited to the working examples. Further, in the working examples, the elements having the same functions are denoted by the same reference symbols and overlapping description of them is omitted herein.

### Working Example 1

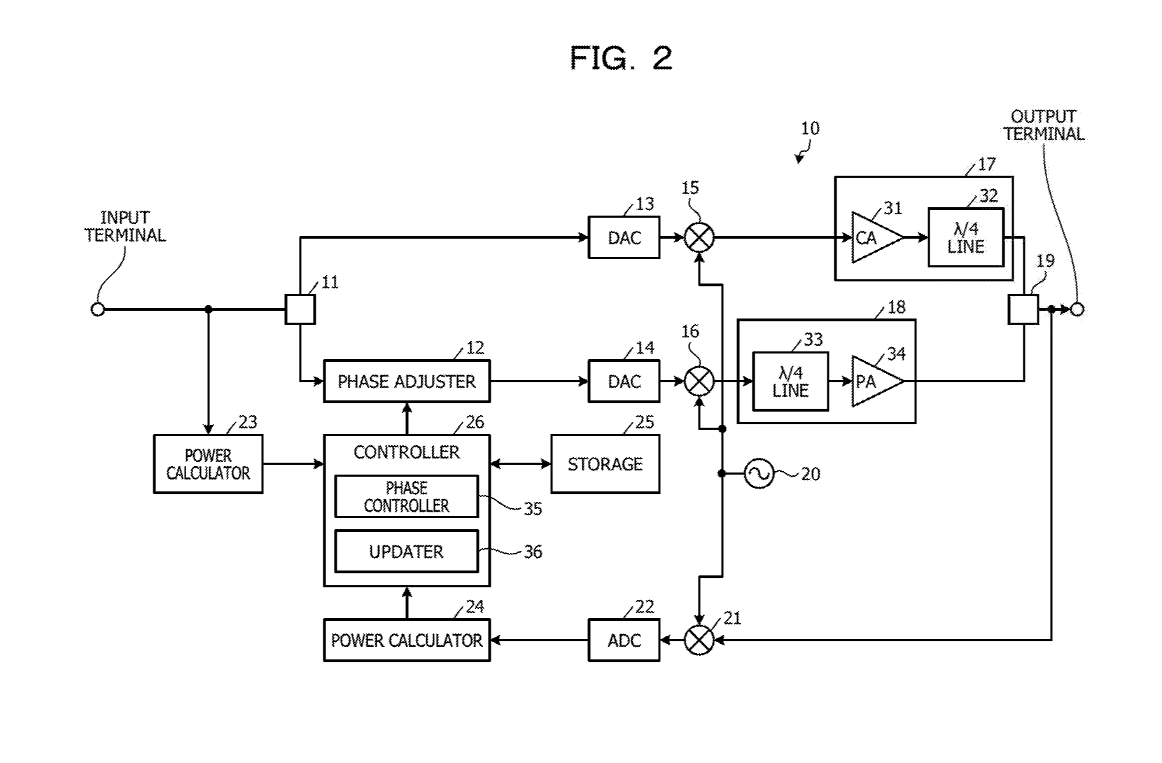

FIG. 2 is a block diagram depicting a configuration of an amplification apparatus according to a working example 1. As depicted in FIG. 2, an amplification apparatus 10 includes a separator 11, a phase adjuster 12, digital to analog converters (DACs) 13 and 14, frequency converters 15 and 16, amplifiers 17 and 18, and a synthesizer 19. The amplification apparatus 10 further includes a reference carrier generator 20, a frequency converter 21, an analog to digital converter (ADC) 22, power calculators 23 and 24, a storage 25, and a controller 26. It is to be noted that the amplification apparatus 10 is a Doherty type amplification apparatus.

The separator 11 separates an input signal inputted from an input terminal of the amplification apparatus 10 into two signals each having a given amplitude value, and outputs one of the two signals obtained by the separation to an upper system (system of the amplifier 17) and outputs the other signal to a lower system (system of the amplifier 18). In the following, a signal outputted from the separator 11 to the system of the amplifier 17 is sometimes referred to as “first signal,” and a signal outputted from the separator 11 to the system of the amplifier 18 is sometimes referred to as “second signal.”

The phase adjuster 12 adjusts the phase of the second signal in accordance with an instruction from the controller 26.

The DAC 13 performs digital to analog conversion of the first signal and outputs a resulting analog first signal to the frequency converter 15. The DAC 14 performs digital to analog conversion of the second signal and outputs a resulting analog second signal to the frequency converter 16.

The frequency converter 15 frequency converts the first signal using a reference carrier generated by the reference carrier generator 20 and outputs the first signal after the frequency conversion to the amplifier 17. The frequency converter 16 frequency convers the second signal using the reference carrier generated by the reference carrier generator 20 and outputs the second signal after the frequency conversion to the amplifier 18.

The amplifier 17 includes a CA 31 and a λ/4 line 32. The CA 31 is an amplifier having a linear property where the input power is lower than a given value and amplifies the first signal. The λ/4 line 32 is coupled to an output end of the CA 31 and converts the output side impedance of the CA 31.

The amplifier 18 includes a λ/4 line 33 and a PA 34. The λ/4 line 33 is a line for compensating for a phase difference between the CA 31 and the PA 34 arising from the λ/4 line 32 coupled to the output end of the CA 31. The PA 34 is an amplifier that is turned on only when the input power is equal to or higher than a given value, and amplifies the second signal.

The synthesizer 19 synthesizes a signal outputted from the amplifier 17 and another signal outputted from the amplifier 18 and outputs an output signal obtained by the synthesis to an output terminal of the amplification apparatus 10. Further, the output signal outputted from the synthesizer 19 to the output terminal is partly fed back as a feedback signal to the frequency converter 21.

The reference carrier generator 20 generates a reference carrier and outputs the generated reference carrier to the frequency converter 15, the frequency converter 16, and the frequency converter 21.

The frequency converter 21 frequency converts an output signal fed back as a feedback signal from the synthesizer 19 using the reference carrier generated by the reference carrier generator 20 and outputs the output signal after the frequency conversion to the ADC 22.

The ADC 22 performs analog to digital conversion of the output signal of the amplification apparatus 10 inputted thereto from the frequency converter 21 and outputs a resulting digital output signal to the power calculator 24.

The power calculator 23 calculates a power value of the input signal inputted thereto from the input terminal of the amplification apparatus 10 and outputs the calculated power value of the input signal to the controller 26.

The power calculator 24 calculates a power value of the output signal inputted thereto from the ADC 22 and outputs the calculated power value of the output signal to the controller 26.

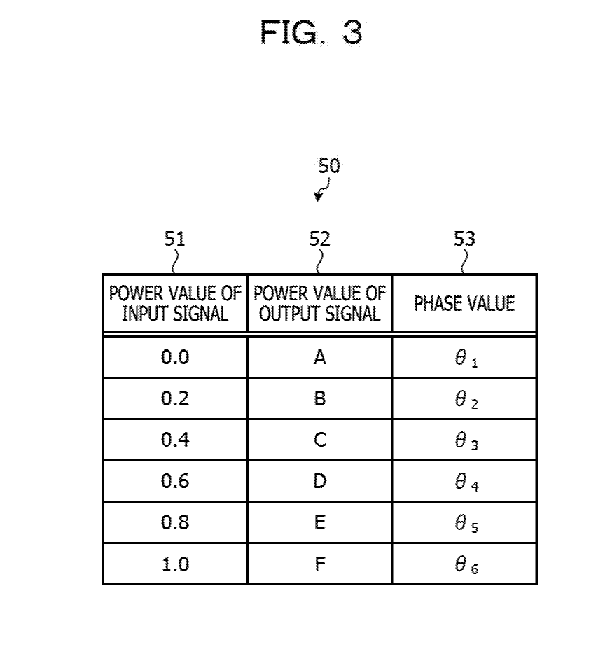

The storage 25 stores an adjustment table used for adjustment of the phase of the second signal by the phase adjuster 12. FIG. 3 is a view illustrating an example of an adjustment table stored in the storage in the working example 1. As depicted in FIG. 3, in an adjustment table 50, a power value 52 of the output signal and a phase value 53 used for adjustment of the phase of the second signal by the phase adjuster 12 are stored in an associated relationship with a power value 51 of the input signal inputted from the input terminal. In the adjustment table 50 exemplified in FIG. 3, power values “A” to “F” of the output signal and phase values “θ₁” to “θ₆” are associated with the power values “0.0” to “1.0” of the input signal, respectively.

Referring back to FIG. 2, the controller 26 includes a phase controller 35 and an updater 36.

The phase controller 35 instructs the phase adjuster 12 to adjust the phase of the second signal within a phase adjustment period within which adjustment of the phase of the second signal is performed by the phase adjuster 12. The phase adjustment period is a transmission period within which, for example, a transmission apparatus that incorporates the amplification apparatus 10 transmits an output signal from the amplification apparatus 10 as a transmission signal. For example, the phase controller 35 refers to the adjustment table 50 in the storage 25 within the phase adjustment period and acquires a phase value according to a power value of an input signal inputted from the power calculator 23. Then, the phase controller 35 instructs the phase adjuster 12 to perform adjustment of the phase of the second signal using the acquired phase value. Consequently, the phase adjuster 12 performs adjustment of the phase of the second signal using the phase value according to the power value of the input signal.

The updater 36 changes a setting phase value set to the phase adjuster 12 within an updating period within which a phase value according to a power value of the input signal, for example, a phase value used for adjustment of the phase of the second signal by the phase adjuster 12, is updated. Then, the updater 36 refers to the adjustment table 50 in the storage 25 and updates the phase value according to the power value of the input signal to the setting phase value after the change using a power value of the output signal calculated by the power calculator 24 with regard to the setting phase value after the change. The updating of the phase value by the updater 36 is hereinafter described in detail.

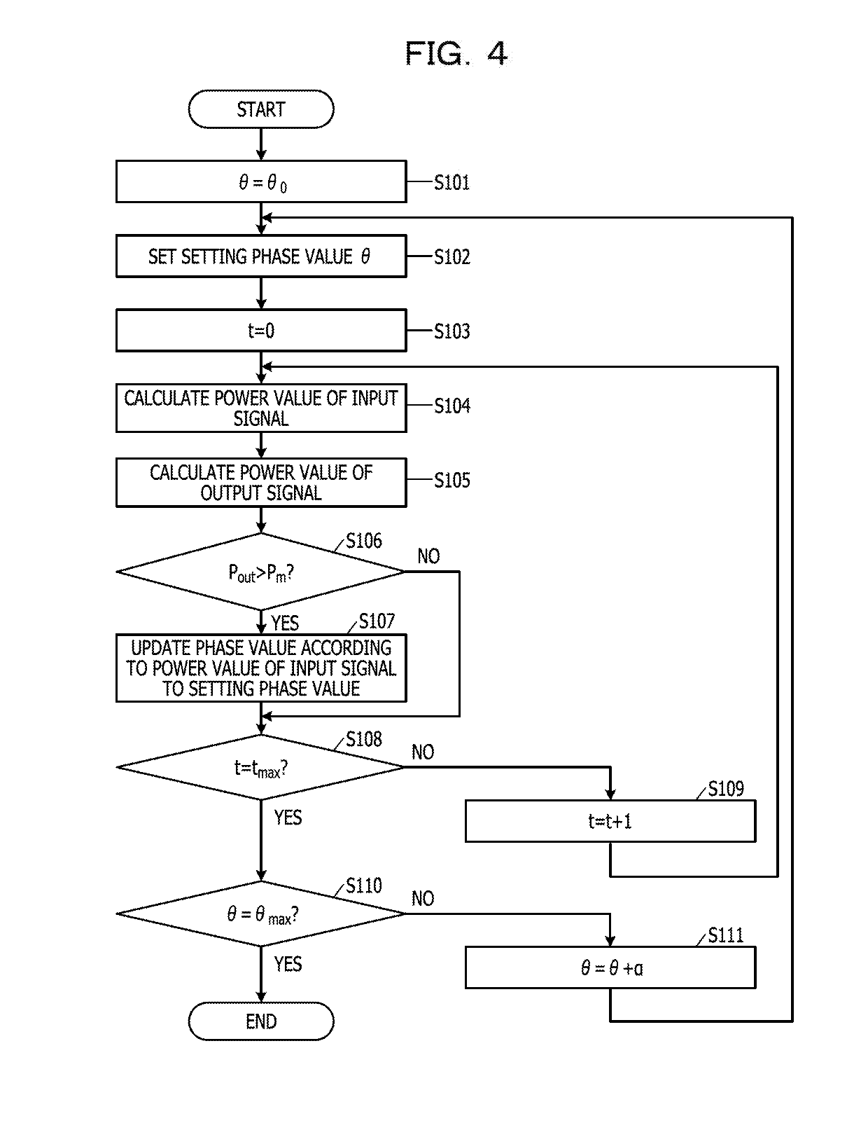

Now, a phase value updating process by the amplification apparatus 10 configured in such a manner as described above is described in connection with a particular example with reference to FIG. 4. FIG. 4 is a flow chart illustrating the phase value updating process according to the working example 1. The phase value updating process illustrated in FIG. 4 is executed principally by the updater 36.

As illustrated in FIG. 4, an initial value θ₀ is set to a parameter θ for changing the setting phase value to be set to the phase adjuster 12 within an updating period (step S101). The initial value θ₀ is, for example, where the setting phase value θ is changed to a plurality of change values existing within a given range, the lowest one of the plurality of change values. The updater 36 sets the setting phase value θ to the phase adjuster 12 (step S102).

If an input signal of time t=0 is inputted to the amplification apparatus 10 (step S103), a power value Pᵢₙ of the input signal is calculated by the power calculator 23 (step S104), and a power value Pₒᵤₜ of the output signal is calculated by the power calculator 24 (step S105).

The updater 36 refers to the adjustment table 50 in the storage 25 and acquires a power value Pₘ of the output signal according to the power value Pᵢₙ of the input signal calculated by the power calculator 23. In the adjustment table 50 in the storage 25, an initial value of the power value of the output signal determined in advance or a power value of the output signal calculated by the power calculator 24 with regard to another setting phase value θ is stored as the power value Pₘ of the output signal. Then, the updater 36 decides whether or not the power value of the output signal calculated with regard to the setting change value at present (for example, the power value Pₒᵤₜ of the output signal calculated at step S105) is higher than the power value Pₘ of the output signal (step S106).

If the power value Pₒᵤₜ of the output signal calculated at step S105 is higher than the power value Pₘ of the output signal (affirmative at step S106), the updater 36 refers to the adjustment table 50 in the storage 25. Then, the updater 36 updates the phase value according to the power value Pᵢₙ of the input signal to the setting phase value θ (step S107). Further, the updater 36 updates the power value Pₘ of the output signal according to the power value Pᵢₙ of the input signal to the power value Pₒᵤₜ of the output signal calculated at step S105.

On the other hand, if the power value Pₒᵤₜ of the output signal calculated at step S105 is equal to or lower than the power value Pₘ of the output signal (negative at step S106), the updater 36 advances the process to step S108 without updating the adjustment table 50 in the storage 25.

If the input signal of time t=tₘₐₓ is not inputted to the amplification apparatus 10 (negative at step S108), time t is incremented by one (step S109), and the respective processes at steps S104 to S108 described above are executed repetitively. Here, tₘₐₓ is a maximum value of time t determined in advance.

If the input signal of t=tₘₐₓ is inputted to the amplification apparatus 10 (affirmative at step S108), it is decided by the updater 36 whether or not the setting change value θ reaches a maximum value θₘₐₓ of the parameter θ (step S110). The maximum value θₘₐₓ of the parameter θ is, where the setting phase value θ is changed to a plurality of change values existing within a given range, the highest change value among the plurality of change values.

If the setting change value θ does not reach the maximum value θₘₐₓ (negative at step S110), the updater 36 changes the setting change value θ only by a change width α (step S111), and the process returns to step S102. Consequently, at step S102, the setting change value θ to be set to the phase adjuster 12 by the updater 36 is changed in order to a plurality of change values existing in the given range. Thereafter, the respective processes at steps S103 to S110 are executed repetitively until after the setting change value θ reaches the maximum value θₘₐₓ. For example, when the power value Pₒᵤₜ of the output signal calculated for each change value of the setting change value θ is higher than the power value Pₘ of the output signal calculated with regard to the other change values, the updater 36 updates the phase value according to the power value Pᵢₙ of the input signal to the individual change values.

If the setting change value θ reaches the maximum value θₘₐₓ (affirmative at step S110), the updater 36 ends the phase value updating process.

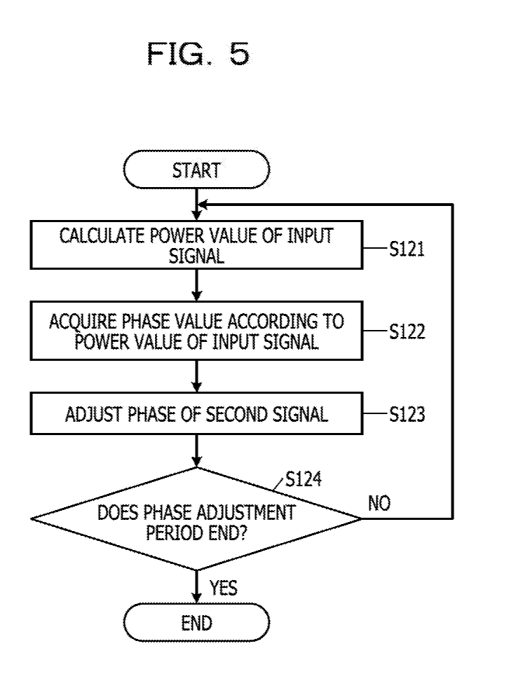

Now, a phase adjustment process by the amplification apparatus 10 is described in connection with a particular example with reference to FIG. 5. FIG. 5 is a flow chart illustrating the phase adjustment process according to the working example 1. The phase adjustment process illustrated in FIG. 5 is executed principally by the phase controller 35.

As depicted in FIG. 5, after a phase adjustment period starts, a power value of the input signal is calculated by the power calculator 23 (step S121).

The phase controller 35 refers to the adjustment table 50 in the storage 25 within the phase adjustment period and acquires a phase value according to the power value of the input signal inputted from the power calculator 23 (step S122).

The phase controller 35 instructs the phase adjuster 12 to perform adjustment of the phase of the second signal using the acquired phase value. Consequently, the phase adjuster 12 performs adjustment of the phase of the second signal using the phase value according to the power value of the input signal (step S123).

If the phase adjustment period does not end (negative at step S124), the phase controller 35 returns the process to step S121, but if the phase adjustment period ends (affirmative at step S124), the phase controller 35 ends the process.

As described above, according to the present working example, the amplification apparatus 10 includes the separator 11, the amplifier 17, the amplifier 18, the phase adjuster 12, the power calculator 24, and the updater 36. The separator 11 separates an input signal to a first signal and a second signal. The amplifier 17 amplifies and outputs the first signal described above. The amplifier 18 amplifies and outputs the second signal described above. The phase adjuster 12 adjusts the phase of the input signal (second signal described above) to the amplifier 18 using a phase value according to the power value of the input signal or a setting phase value set within an updating period for updating the phase value in question. The power calculator 24 calculates the power value of the output signal synthesized from an output of the amplifier 17 and an output of the amplifier 18. The updater 36 changes, within the updating period described above, the setting phase value set to the phase adjuster 12 and updates the phase value according to the power value of the input signal to the setting phase value after the change using the power value of the output signal calculated with regard to the setting phase value after the change.

By the configuration of the amplification apparatus 10, the phase value used for adjustment of the phase of the input signal to the amplifier 18 (second signal described above) is updated sequentially such that the output power may be maximized. Consequently, in the amplification apparatus 10 of the Doherty type in which the amplifier 17 (CA 31) and the amplifier 18 (PA 34) are coupled in parallel, the load impedance of the CA 31 and the PA 34 comes close to the real axis of the Smith chart (for example, the broken line in FIG. 1). Accordingly, the efficiency and the output power of the amplification apparatus 10 assume maximum values. As a result, the efficiency and the output power of the amplification apparatus 10 are improved.

Further, in the amplification apparatus 10, the updater 36 changes the setting phase value in order to a plurality of change values existing within a given range. Then, when the power value of the output signal calculated with regard to any change value is higher than the power values of the output signal calculated with regard to the other change values, the updater 36 updates the phase value according to the power value of the input signal to the individual change values.

By this configuration of the amplification apparatus 10, an optimum change value with which the power value of the output signal is maximized is searched out from among a plurality of change values existing within a given range, and the phase value according to the power value of the input signal is updated to the searched out optimum change value. As a result, the efficiency and the output power of the amplification apparatus 10 are further improved.

It is to be noted that, while, in the working example 1 described above, a value determined in advance is used as the initial value θ₀ of the setting phase value θ, the disclosed technology is not limited to this. For example, the updater 36 may execute, before an updating period comes, the phase value updating process described hereinabove to determine an optimum value of the phase value according to the power value of the input signal at a certain point of time and set the determined optimum value to the initial value θ₀ for all of the setting phase values θ within the updating period. Further, an average value of the power value of a given number of input signals or a power value of an input signal when both of the CA 31 and the PA 34 operate may be used in place of the power value of the input signal at a certain point of time.

### Working Example 2

A working example 2 relates to a variation of the updating method of a phase value according to the power value of an input signal. It is to be noted that the basic configuration of an amplification apparatus of the working example 2 is similar to that of the amplification apparatus 10 of the working example 1, and therefore is described with reference to FIG. 2.

In an amplification apparatus 10 of the working example 2, when the power value Pₒᵤₜ of the output signal calculated for any change value of the setting change value θ is equal to or lower than the power value Pₘ of the output signal calculated with regard to the other change values, the updater 36 does not perform updating of the phase value according to the power value of the input signal. Then, the updater 36 reduces the change width α of the setting phase value θ and besides reverses the changing direction of the setting phase value θ.

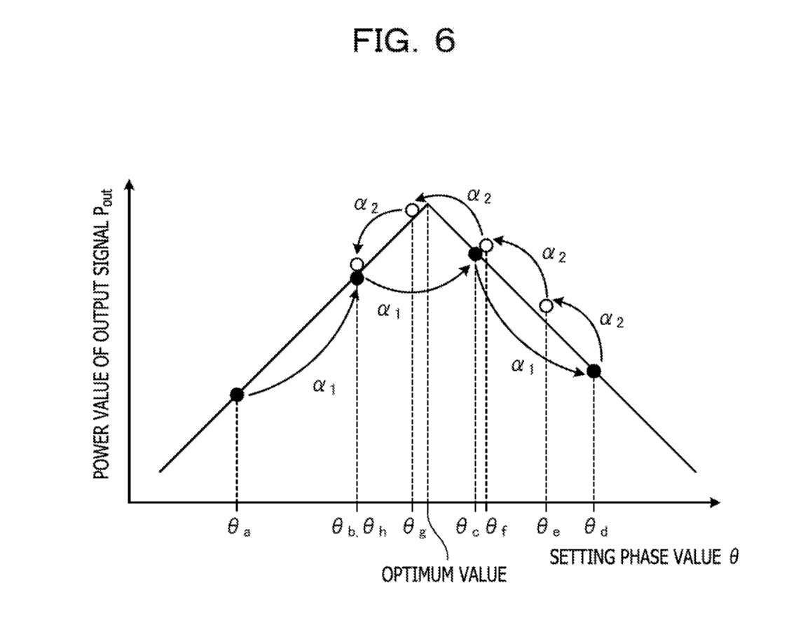

FIG. 6 is a view illustrating an example of operation of the updater in a working example 2. The updater 36 first sets the setting phase value θ to an initial value θₐ. The updater 36 changes the setting phase value θ from the initial value θₐ to a change value θ_{b} by adding the change width α₁ to the setting phase value θ. Since the power value Pₒᵤₜ of the output signal calculated by the power calculator 24 with regard to the change value θ_{b} is higher than the power value Pₒᵤₜ of the output signal calculated with regard to the initial value θₐ, the updater 36 updates the phase value according to the power value of the input signal to the change value θ_{b}. Such an updating process as just described is repeated until the power value Pₒᵤₜ of the output signal calculated by the power calculator 24 with regard to the change value becomes equal to or lower than the power value Pₒᵤₜ of the output signal calculated with regard to the other change values. Since the power value Pₒᵤₜ of the output signal calculated with regard to a change value θ_{d} of the setting change value θ is equal to or lower than the power value Pₘ of the output signal calculated with regard to a change value θ_{c}, the updater 36 does not perform updating of the phase value according to the power value of the input signal. In this case, the updater 36 reduces the change width α₁ of the setting phase value θ to another change width α₂ smaller than the change width α₁ and besides reverses the changing direction of the setting phase value θ. For example, the updater 36 changes the setting phase value θ from the change value θ_{d} to another change value θₑ by subtracting the change width α₂ from the setting phase value θ. Since the power value Pₒᵤₜ of the output signal calculated by the power calculator 24 with regard to the change value θₑ is greater than the power value Pₒᵤₜ of the output signal calculated with regard to the change value θ_{d}, the updater 36 updates the phase value according to the power value of the input signal to the change value θₑ. Such an updating process as just described is repeated until the power value Pₒᵤₜ of the output signal calculated by the power calculator 24 with regard to the change value becomes equal to or lower than the power value Pₒᵤₜ of the output signal calculated with regard to the other change values. Since the power value Pₒᵤₜ of the out signal calculated with regard to a change value θₕ of the setting change value θ is equal to or lower than the power value Pₘ of the output signal calculated with regard to a change value θ_{g}, the updater 36 does not perform updating of the phase value according to the power value of the input signal. In this case, the updater 36 reduces the change width α₂ of the setting phase value θ to a change width smaller than the change width α₂ and besides reverses the changing direction of the setting phase value θ. The sequence of processes described above is repeated until after the change width α of the setting phase value θ becomes a value determined in advance. Consequently, the setting phase value θ gradually approaches an optimum change value with which the power value of the output signal is maximized.

As described above, according to the present working example, in the amplification apparatus 10, when the power value of the output signal calculated with regard to any change value of the setting phase value is equal to or lower than the power value of the output signal calculated with regard to the other change values, the updater 36 does not perform updating of the phase value. Then, the updater 36 reduces the change width of the setting phase value and besides reverses the changing direction of the setting phase value.

By the configuration of the amplification apparatus 10, an optimum change value that maximizes the power value of the output signal is searched out at a higher speed from among a plurality of change values existing within a given range. As a result, the updating speed of the phase value according to the power value of the input signal is improved.

### Working Example 3

In a working example 3, the power value of the output signal is averaged and the phase value used for adjustment of the phase of the input signal (second signal described above) to the amplifier 18 is updated with a high degree of accuracy.

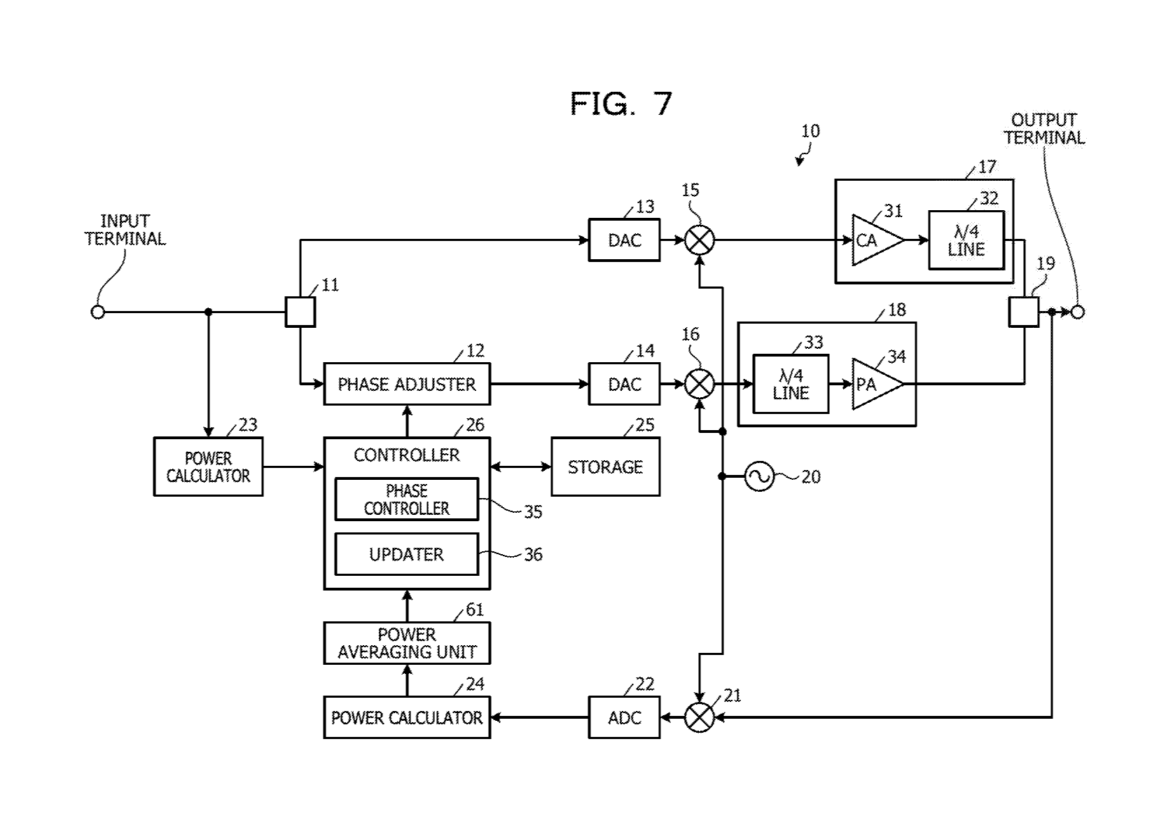

FIG. 7 is a block diagram depicting a configuration of an amplification apparatus according to a working example 3. As depicted in FIG. 7, an amplification apparatus 10 of the working example 3 includes a power averaging unit 61. The power averaging unit 61 averages the power value of the output signal calculated by the power calculator 24. Since the output signal includes various noise components, the power value of the output signal calculated by the power calculator 24 is sometimes influenced by the noise components described above. In contrast, in the present working example, since the power value of the output signal calculated by the power calculator 24 is averaged by the power averaging unit 61, the influence of the noise components described above is reduced.

Further, in the amplification apparatus 10 of the working example 3, the updater 36 changes, within an updating period, the setting phase value to be set to the phase adjuster 12. Then, the updater 36 refers to the adjustment table 50 in the storage 25 and updates the phase value according to the power value of the input signal to a setting phase value after the change using the power value of the output signal calculated by the power calculator 24 with regard to the setting phase value after the change and averaged by the power averaging unit 61.

As described above, according to the present working example, the power averaging unit 61 in the amplification apparatus 10 averages the power value of the output signal calculated by the power calculator 24. Then, the updater 36 updates the phase value according to the power value of the input signal to the setting phase value after the change using the power value of the output signal calculated by the power calculator 24 with regard to the setting phase value after the change and averaged by the power averaging unit 61.

By the configuration of the amplification apparatus 10, the influence of noise components included in the output signal is reduced, and it is possible to update the phase value according to the power value of the input signal with a high degree of accuracy using the power value of the output signal. As a result, the efficiency and the output power of the amplification apparatus 10 are improved further.

### Working Example 4

A working example 4 relates to a variation to the updating method for a phase value according to the power value of an input signal. It is to be noted that the basic configuration of an amplification apparatus of the working example 4 is similar to that of the amplification apparatus 10 of the working example 1, and therefore is described with reference to FIG. 2.

In an amplification apparatus 10 of the working example 4, when the power value of the input signal is equal to or higher than a threshold value within an updating period, the updater 36 performs updating of the phase value according to the power value of the input signal. On the other hand, if the power value of the input signal is lower than the threshold value within an updating period, the updater 36 does not perform updating of the phase value according to the power value of the input signal. As the threshold value, for example, a power value of the input signal when both of the CA 31 and the PA 34 operate is used. A situation in which the threshold value is a power value of the input signal when both of the CA 31 and the PA 34 operate is supposed. In this situation, when the power value of the input signal is lower than the power value of the input signal when both of the CA 31 and the PA 34 operate, for example, when the power value of the input signal is a power value of the input signal when only the CA 31 operates, the updater 36 does not perform updating of the phase value.

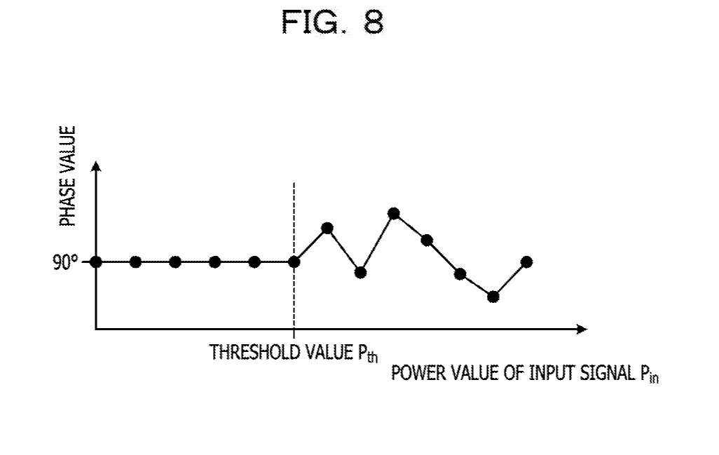

FIG. 8 is a view illustrating an example of operation of the updater in the working example 4. As depicted in FIG. 8, when the power value Pᵢₙ of the input signal calculated by the power calculator 23 within an updating period is lower than a threshold value Pₜₕ, the updater 36 does not perform updating of the phase value according to the power value Pᵢₙ of the input signal. In the example of FIG. 8, when the power value Pᵢₙ of the input signal calculated by the power calculator 23 is lower than the threshold value Pₜₕ, the phase value according to the power value Pᵢₙ of the input signal is set to a fixed value of 90 degrees.

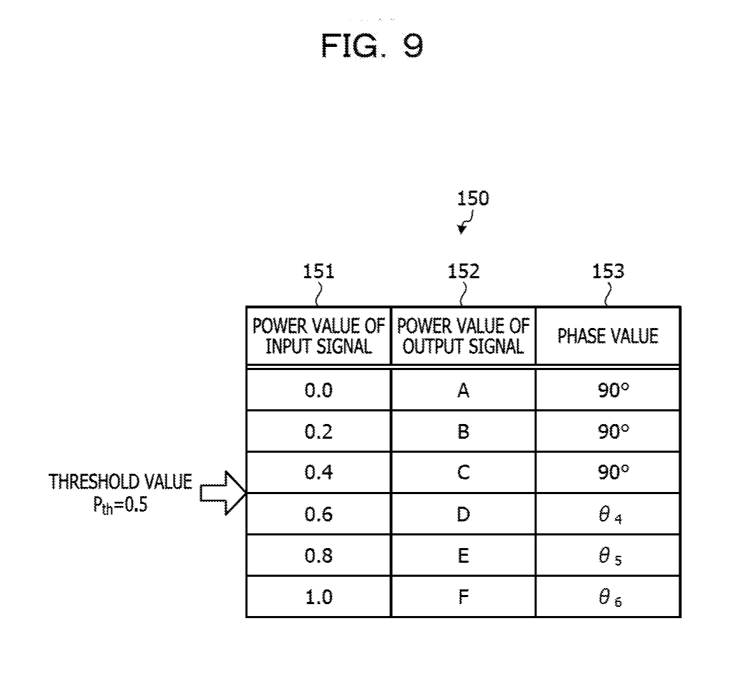

Further, in the amplification apparatus 10 in the working example 4, the storage 25 stores an adjustment table used for adjustment of the phase of the second signal by the phase adjuster 12. FIG. 9 is a view illustrating an example of an adjustment table stored in the storage in the working example 4. As depicted in FIG. 9, in an adjustment table 150, a power value 152 of the output signal and a phase value 153 used for adjustment of the phase of the second signal by the phase adjuster 12 are stored in an associated relationship with a power value 151 of the input signal inputted from the input terminal. In the adjustment table 150 illustrated in FIG. 9, the threshold value Pₜₕ is set to “0.5.” When the power value Pᵢₙ of the input signal is “0.0” to “0.4” lower than the threshold value 0.5 within an updating period, the updater 36 does not perform updating of the phase value according to the power value of the input signal. Therefore, in the adjustment table 150 exemplified in FIG. 9, the phase value according to the power value Pᵢₙ of the input signal is set to 90 degrees.

As described above, according to the present working example, in the amplification apparatus 10, when the power value of the input signal is equal to or higher than the threshold value within an updating period, the updater 36 performs updating of the phase value according to the power value of the input signal. On the other hand, when the power value of the input signal is lower than the threshold value within an updating period, the updater 36 does not perform updating of the phase value according to the power value of the input signal.

By the configuration of the amplification apparatus 10, when the power value of the input signal is lower than the threshold value, since updating of the phase value according to the power value of the input signal is not performed, the process amount in updating of the phase value according to the power value of the input signal may be reduced.

### Working Example 5

A working example 5 relates to a variation to the updating method of a phase value according to the power value of an input signal. It is to be noted that the basic configuration of an amplification apparatus of the working example 5 is similar to that of the amplification apparatus 10 of the working example 1, and therefore is described with reference to FIG. 2.

In an amplification apparatus 10 of the working example 5, when the power value of the input signal is equal to or higher than the threshold value within an updating period, the updater 36 performs updating of the phase value according to the power value of the input signal. On the other hand, when the power value of the input signal is lower than the threshold value within an updating period, the updater 36 replaces the phase value according to the power value of the input signal to another phase value according to the threshold value.

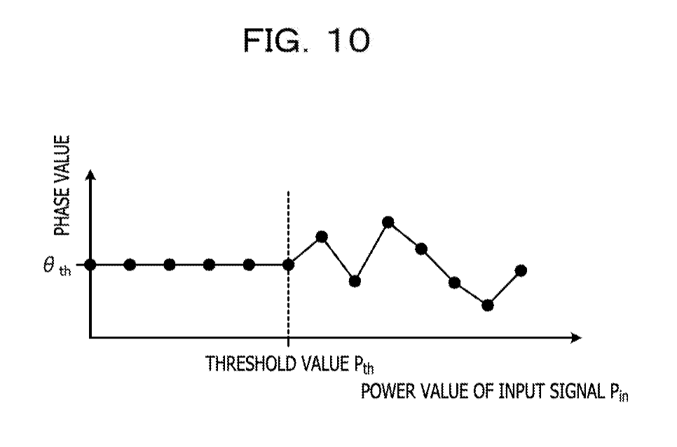

FIG. 10 is a view illustrating an example of operation of the updater in the working example 5. In the example of FIG. 10, it is assumed that the phase value according to the threshold value Pₜₕ is θₜₕ. As depicted in FIG. 10, when the power value Pᵢₙ of the input signal calculated by the power calculator 23 is lower than the threshold value Pₜₕ within an updating period, the updater 36 replaces the phase value according to the power value Pᵢₙ of the input signal to the phase value θₜₕ according to the threshold value Pₜₕ.

As described above, according to the present working example, in the amplification apparatus 10, when the power value of the input signal is equal to or higher than the threshold value within an updating period, the updater 36 performs updating of the phase value according to the power value of the input signal. On the other hand, when the power value of the input signal is lower than the threshold value within an updating period, the updater 36 replaces the phase value according to the power value of the input signal to another phase value according to the threshold value.

By the configuration of the amplification apparatus 10, when the power value of the input signal is lower than the threshold value, since the phase value according to the power value of the input signal is replaced to the phase value according to the threshold value, the process amount in updating of the phase value according to the power value of the input signal may be reduced.

### Working Example 6

A working example 6 relates to an example in which any of the updating methods for a phase value described in connection with the working examples 1 to 5 is applied to a combination of phase adjustment and distortion compensation. For example, updating of a phase value according to the power value of the input signal and compensation for distortion that arises in the amplification apparatus are performed time-divisionally.

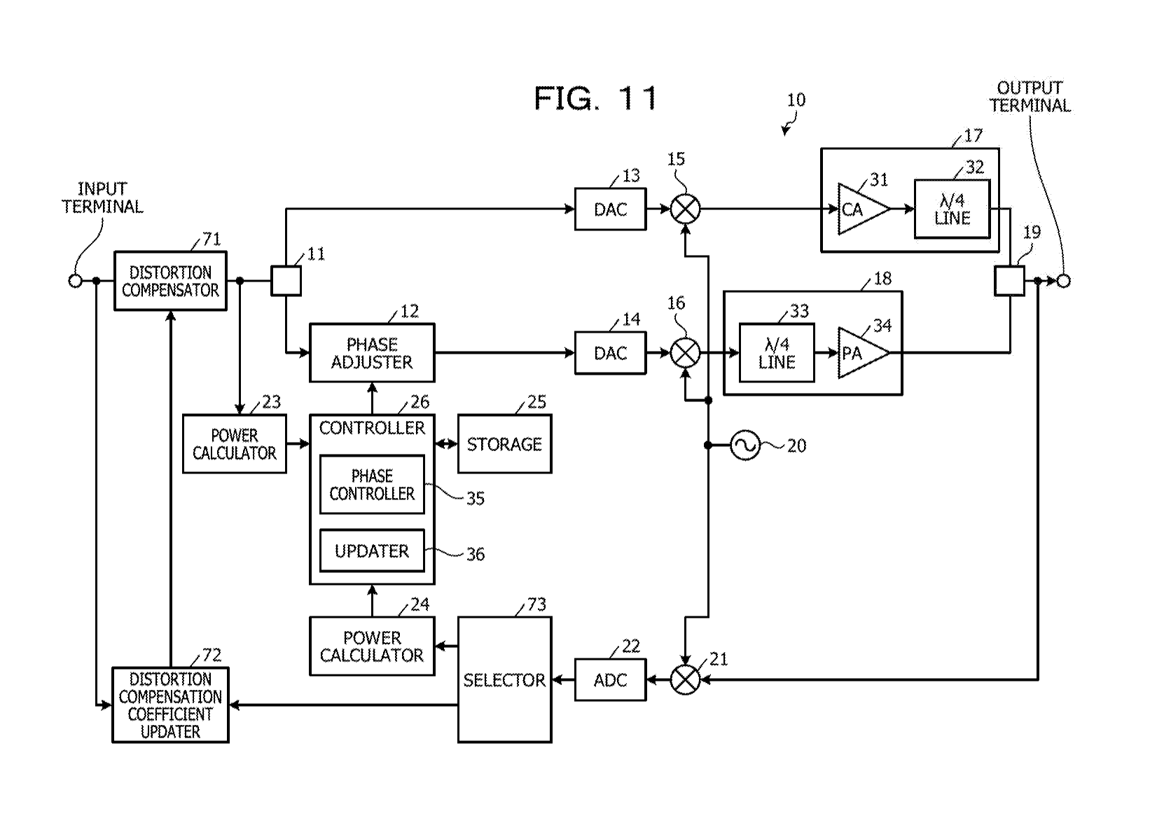

FIG. 11 is a block diagram depicting a configuration of an amplification apparatus according to the working example 6. As depicted in FIG. 11, an amplification apparatus 10 of the working example 6 includes a distortion compensator 71, a distortion compensation coefficient updater 72, and a selector 73.

The distortion compensator 71 performs a distortion compensation process for the input signal using a distortion compensation coefficient. For example, the distortion compensator 71 compensates for distortion that arises in the output signal. For example, the distortion compensator 71 retains a look up table (LUT) that retains distortion compensation coefficients. The distortion compensator 71 reads out a distortion compensation coefficient from the LUT using an amplitude value of the input signal as an address, multiplies the input signal by the read out distortion compensation coefficient, and outputs the input signal after the distortion compensation process.

The distortion compensation coefficient updater 72 calculates an updating value for a distortion compensation coefficient with which the error between the input signal and the output signal is minimized and updates the distortion compensation coefficient in the LUT of the distortion compensator 71 with the calculated updating value.

The selector 73 is coupled to an output of the ADC 22 and time-divisionally selects one of the power calculator 24 and the distortion compensation coefficient updater 72 as an output destination of the output signal inputted from the ADC 22. If the power calculator 24 is selected by the selector 73, the power value of the output signal is calculated by the power calculator 24. On the other hand, if the distortion compensation coefficient updater 72 is selected by the selector 73, an updating value for the distortion compensation coefficient with which the error between the input signal and the output signal is minimized is calculated by the distortion compensation coefficient updater 72.

In such a manner as described above, even where phase adjustment and distortion compensation are combined, the phase value used for adjustment of the phase of the input signal (second signal described above) to the amplifier 18 is updated sequentially such that the output power is maximized. As a result, the efficiency and the output power of the amplification apparatus 10 are improved.

### Other Working Examples

The power calculator 23, the power calculator 24, the controller 26, the phase controller 35, and the updater 36 are implemented, for example, by a field programmable gate array (FPGA), a large scale integrated (LSI) circuit, a processor or the like as hardware. Further, the power averaging unit 61, the distortion compensator 71, and the distortion compensation coefficient updater 72 are implemented, for example, by an FPGA, an LSI circuit, a processor or the like as hardware. Further, the separator 11, the phase adjuster 12, the DAC 13, the DAC 14, the frequency converter 15, the frequency converter 16, the amplifier 17, the amplifier 18, the synthesizer 19, the reference carrier generator 20, the frequency converter 21, the ADC 22, and the selector 73 are implemented, for example, by analog circuits as hardware. Further, the storage 25 is implemented, for example, by a memory.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An amplification apparatus comprising:
a separator configured to separate an input signal into a first signal and a second signal;
a first amplifier configured to amplify the first signal;
a second amplifier configured to amplify the second signal;
a storage; and
a processor coupled to the storage and configured to:
adjust a phase of the second signal on the basis of a first phase value corresponding to a power value of the input signal or a second phase value set within a period in which the first phase value is updated;
calculate a power value of an output signal that is synthesis of an output of the first amplifier and an output of the second amplifier; and
update the first phase value to the second phase value after the change of the power value of the calculated output signal when the first phase value is the power value of the input signal.

2. The amplification apparatus according to claim 1, the processor further configured to:
change the setting phase value in order to a plurality of change values existing within a given range and updates; and
change the specified phase value according to the power value of the input signal to the change value when the power value of the output signal calculated with regard to any of the change values is higher than the power value of the output signal calculated with regard to another change value.

3. The amplification apparatus according to claim 2, the processor further configured to:
cancel updating the specified phase value;
reduce a change width for the setting phase value; and
reverse a changing direction of the setting phase value when the power value of the calculated output signal with regard to any of the change values is equal to or lower than the power value of the output signal calculated with regard to the other change value.

4. The amplification apparatus according to claim 1, the processor further configured to:
average the power value of the calculated output signal; and
update the specified phase value according to the power value of the input signal to the setting phase value after the change using the power value of the calculated output signal with regard to the setting phase value after the change and averaged.

5. The amplification apparatus according to claim 1, the processor further configured to:
update the specified phase value according to the power value of the input signal when the power value of the input signal is equal to or higher than a threshold value within the period; and
cancel updating the specified phase value according to the power value of the input signal when the power value of the input signal is lower than the threshold value.

6. The amplification apparatus according to claim 1 the processor further configured to:
update the specified phase value according to the power value of the input signal when the power value of the input signal is equal to or higher than a threshold value within the period; and
replace the specified phase value according to the power value of the input signal to a phase value according to the threshold value when the power value of the input signal is lower than the threshold value.

7. The amplification apparatus according to claim 1, the processor further configured to:
perform a distortion compensation process for the input signal using a distortion compensation coefficient;
update the distortion compensation coefficient based on an error between the input signal and the output signal; and
time-divisionally select calculating and distortion compensation coefficient updating as an output destination of the output signal.
